(19) United States
(12) Patent Application Publication
(10) Pub. No.: US 2014/0264630 A1
(43) Pub. Date: Sep. 18, 2014

(54) Integrated Structure

(71) Applicants: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(72) Inventors: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(21) Appl. No.: 13/832,844

(22) Filed: Mar. 15, 2013

(51) Int. Cl. H01L 23/48

(52) U.S. Cl. CPC H01L 23/481
USPC 257/401

(57) ABSTRACT

An integrated structure comprises a substrate with a first dielectric layer and a second dielectric cap layer disposed thereon in sequence, a metal gate transistor with a high-k gate dielectric layer on the substrate, a gate electrode embedded within the first dielectric layer and a source/drain within the substrate, a first metal contact penetrating the first dielectric layer and being in direct contact with the source/drain and a through-silicon via penetrating the second dielectric cap layer, the first dielectric layer and the substrate.

### FIELD OF THE INVENTION

The present invention relates to an integrated structure and particularly to an integrated structure with a through-silicon via.

### BACKGROUND OF THE INVENTION

To save precious layout space or increase interconnection efficiency, multiple chips of integrated circuits (ICs) can be stacked together as a single IC package. To that end, a three-dimensional (3D) stack packaging technology is used to package the chips of integrated circuits. Through-silicon vias (TSVs) are widely used to accomplish the 3D stack packaging technology. A through-silicon via is a vertical conductive via completely passing through a silicon wafer, a silicon board, a substrate of any material or die. Nowadays, a 3D integrated circuit (3D IC) is applied to a lot of fields such as memory stacks, image sensors or the like.

The process of manufacturing integrated circuits with through-silicon vias has many integration issues and one of them is copper extrusion. Compared to a single transistor or a single interconnect metal line, a through silicon via comes with a size of hundred fold or more. The mechanical stress, properties mismatch or electrical impacts caused by a through silicon via of such a size can not be neglected, so there is a need to propose a better integrated process of manufacturing integrated circuits with through-silicon vias.

### SUMMARY OF THE INVENTION

A purpose of this invention is to provide an integrated structure with a through-silicon via. This integrated structure with a through-silicon via comprises a substrate with a first dielectric layer and a second dielectric cap layer disposed thereon in sequence, a metal gate transistor with a high-k gate dielectric layer on the substrate, a gate electrode embedded within the first dielectric layer and a source/drain within the substrate, a first metal contact penetrating the first dielectric layer and being in direct contact with the source/drain and a through-silicon via penetrating the second dielectric cap layer, the first dielectric layer and the substrate.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1-4 and 5A shows schematic cross-sectional views illustrating a method of manufacturing an integrated structure with TSV in accordance with first embodiment of the present invention;

FIG. 5B shows a schematic cross-sectional view illustrating an integrated structure with TSV in accordance with second embodiment of the present invention;

FIG. 6A shows a schematic cross-sectional view illustrating an integrated structure with TSV in accordance with third embodiment of the present invention;

FIG. 6B shows a schematic cross-sectional view illustrating an integrated structure with TSV in accordance with fourth embodiment of the present invention;

FIG. 7 shows the schematic final result of the integrated structure with TSV in accordance with first embodiment of the present invention.

### DETAILED DESCRIPTION OF PREFERRED EMBODIMENTS

The following is the detailed description of the preferred embodiments of this invention. All the elements, sub-elements, structures, materials, arrangements recited herein can be combined in any way and in any order into new embodiments, and these new embodiments should fall in the scope of this invention defined by the appended claims. A person skilled in the art, upon reading this invention, should be able to modify and change the elements, sub-elements, structures, materials, arrangements recited herein without being apart from the principle and spirit of this invention. Therefore, these modifications and changes should fall in the scope of this invention defined only by the following claims.

There are a lot of embodiments and figures in this application. To avoid confusions, similar components are represented by same or similar numerals. To avoid complexity and confusions, only one of the repetitive components is marked. Figures are meant to deliver the principle and spirits of this invention, so the distance, size, ratio, shape, connection relationship, etc. are examples instead of realities. Other distance, size, ratio, shape, connection relationship, etc. capable of achieving the same functions or results can be adopted as equivalents.

Please refer to FIGS. 1-4 and 5A, which are schematic cross-sectional views illustrating a method of manufacturing an integrated structure with TSV in accordance with first embodiment of the present invention. As shown in FIG. 1, a semiconductor substrate 100 is provided. The semiconductor substrate 100 includes silicon substrate, silicon-containing substrate, or silicon-on-insulator (SOI) substrate. Then, a high-k metal gate transistor 250 is formed on the semiconductor substrate 100 embedded in a contact etch stop layer 261 and a first inter-layer dielectric layer 262. The term “high-k metal gate” here means a transistor with metal as its gate electrode and high dielectric constant (high-k) material as its gate dielectric layer. Although in FIG. 1, the high-k metal gate transistor 250 seems to be fabricated by high-k last and gate last process, transistor 250 simply represents a transistor that can be made by any process such as high-k first and gate first process, high-k first and gate last process, high-k last and gate last process and transistor 250 can be either a p-type transistor or an n-type transistor.

As shown in FIG. 1, the high-k metal gate transistor 250 includes an optional buffer layer 231, an U-shaped high-k gate dielectric layer 232 as gate dielectric layer, an U-shaped work function layer 233 and a low-resistivity filling metal 234 together as gate electrode, a spacer 221 and a source and drain (S/D) 222. In the preferred embodiment, the optional buffer layer 231 can be a conventional silicon oxide (SiO) layer to separate the high-k gate dielectric layer 232 and substrate 100. The high-k gate dielectric layer 232 is selected from the group consisting of silicon nitride (SiN), silicon oxynitride (SiON) and metal oxide. And the metal oxide comprises hafnium oxide (HfO), hafnium silicon oxide (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), zirconium silicon oxide (ZrSiO), or hafnium zirconium oxide (HfZrO). The U-shaped work function layer 233 is selected from an n-type work function material (work function between about 3.9 eV and about 4.3 eV, such as TiAl, TiAlN, ZrAl, WAl, TaAl, HfAl), a p-type work function material (work function between about 4.8 eV and about 5.2 eV, such as TiN, TaC) and a mid-gate work function material (TiN with some impurities is commonly used) depending on the performance concern and the conductivity of the transistor 250. The low-resistivity filling metal 234 can be a multi-layered structure and its material/materials can be selected from the group consisting of Al, Ti, Ta, W, Nb, Mo, Cu, TiN, TiC, TaN, Ti/W and Ti/TiN. In a preferred embodiment, the U-shaped work function layer 233 comprises TiN if for PMOS or comprises TiAl if for NMOS, and the low-resistivity filling metal 234 comprises Al. The spacer 221 can be a multi-layered structure comprising high temperature oxide (HTO), SiN, SiO, SiC, SiON or SiN formed by hexachlorodisilane (Si₂Cl₆) (HCD-SiN). The source/drain (S/D) 222 is formed by dopants distributed in the substrate besides the gate electrode. The conductive type and species of the dopants depend on the conductive type of the transistor 250 and performance concerns. Additionally, selective epitaxial growth (SEG) method can be utilized to form raised source/drain 222 (not shown in FIG. 1). For example, when the transistor 250 is a PMOS transistor, epitaxial silicon layers with SiGe can be used to form the source/drain 222; when the transistor 250 is an NMOS transistor, epitaxial silicon layers with SiC or SiP can be used to form the source/drain 222. It is noted that in order to remove excess materials from the transistor 250 and form a global flat surface, a chemical mechanical polishing process may be performed before finishing the transistor 250 shown in FIG. 1.

Now refer to FIG. 2, a first cap layer 272 is formed on the flat surface. Then, at least one contact hole 273 is formed in the first cap layer 272, first inter-layer dielectric layer 262 and contact etch stop layer 261. The first cap layer 272 comprises one or more dielectric materials selected from silicon dioxide, silicon nitride, TEOS-based silicon oxide, SiC, SiON, SiCO, SiCON and polymer. The process used to form the at least one contact hole 273 includes at least one photolithography process and at least one etching process. More than one etching processes may be involved if the first cap layer 272, first inter-layer dielectric layer 262 and contact etch stop layer 261 use different materials. Since pitch of contact (hence other layers) becomes smaller and smaller, it is reasonable to use a so-called 2P2E process (that is, two phtolithography processes and two etching processes) to form contact holes. Although in FIG. 2 only one contact hole 273 exposing the source/drain 222 is shown, this contact hole 273 represents all the contact holes formed in the first cap layer 272, first inter-layer dielectric layer 262 and contact etch stop layer 261 and any contact holes formed in one of the first cap layer 272, first inter-layer dielectric layer 262 and contact etch stop layer 261. For example, a contact hole may land on the gate electrode of the transistor 250 and be in contact with the low-resistivity filling metal 234. For example, a contact hole may land on both the S/D 222 and the gate electrode of transistor 250 and be in contact with both of them. Not only the location but also the shape of the contact is not limited. For example, the sidewall of the contact hole could be extremely vertical or it could be slightly tapered. For example, in order to contact both the S/D 222 and the gate electrode of transistor 250, the contact may be oval-shaped. Furthermore, after forming the contact hole 273 a silicide layer (not shown in FIG. 2) may be formed in the bottom of the contact hole 273 in direct contact with the S/D 222.

Now refer to FIG. 3, a contact 270 is formed in the contact hole 273 and a second cap layer 282 is formed on the first cap layer 272. Then, a big trench 283 configured to be used for through-silicon via is formed in the second cap layer 282, first cap layer 272, first inter-layer dielectric layer 262, contact etch stop layer 261 and substrate 100. The contact 270 may be formed by forming one or more conductive materials on the substrate filling in the contact hole 273 then performing a chemical mechanical polishing process to remove excess materials and form a global flat surface. The conductive materials used for contact 270 comprise a barrier/glue material and a low-resistivity filling material. The barrier/glue material may be selected from Ta, TaN, Ti, TiN, W, WN, Mo, Mn, Cu, and the barrier/glue material preferably be Ta/TaN or Ti/TiN. The low-resistivity filling material may be selected from W, Cu, Al, poly silicon and the low-resistivity filling material preferably is W. The second cap layer 282 comprises one or more dielectric materials selected from silicon dioxide, silicon nitride, TEOS-based silicon oxide, SiC, SiON, SiCO, SiCON and polymer, and the second cap layer 282 preferably is silicon nitride or SiC. The process used to form the big trench 283 includes at least one photolithography process and at least one etching process. Considering the gigantic size of the trench 283 (few μm to tens of μm in diameter, few μm to hundreds of μm in depth) compared to normal contact (few nm to tens of nm in diameter, tens of nm in depth), the photoresist, the etching species and the etching recipe used may be customized.

Now refer to FIG. 4, an electrical-isolating layer (not shown) is formed in the trench 283 lining the sidewall and bottom surfaces of trench 283 and conductive materials (not shown) are formed in the trench 283 filling the trench 283. After forming the electrical-isolating layer and the conductive materials, a chemical mechanical polishing process is perform to remove excess materials, to form a global flat surface and to complete the transient through-silicon via (TSV) 280 comprising an electrical-isolating layer 281 and a conductive via 282. The electrical-isolating layer may be formed by thermal oxidation, then it would not be formed on the sidewalls of the second cap layer 282, first cap layer 272, first inter-layer dielectric layer 262, contact etch stop layer 261 and top surface of the second cap layer 282. Or the electrical-isolating layer may be formed by a deposition process such as a traditional chemical vapor deposition (CVD) process, a flowable CVD process, a plasma-enhanced CVD process, a high density plasma CVD process. The electrical-isolating layer may comprise one or more materials selected from silicon dioxide, silicon nitride, SiON, SiC, SiCN, polymer, and the electrical-isolating layer is preferably a single-layered silicon dioxide layer. The conductive materials used for conductive via 282 comprise a barrier/glue material, an optional seed material and a low-resistivity filling material. The barrier/glue material may be selected from Ta, TaN, Ti, TiN, W, WN, Mo, Mn, Cu. The optional seed material usually matches the low-resistivity filling material, and they may be selected from W, Cu, Al and poly silicon. The low-resistivity filling material preferably is Cu formed by electrode plating and the optional seed material is Cu formed by physical sputtering deposition.

In FIG. 4, it is clearly to see the height d1 of the high-k metal gate 250 (distance from top surface of the substrate 100 to top surface of the low-resistivity filling metal 234) is smaller than the height d2 of the contact 270 (distance from top surface of the substrate 100 to top surface of the contact 270) due to thickness of the first cap layer 272. It is also clearly to see the height d2 of the contact 270 is smaller than the height d3 of the transient TSV 280 above the substrate (distance from top surface of the substrate 100 to top surface of the transient TSV 280) due to thickness of the second cap layer 282.

Now refer to FIG. 5A, a second inter-layer dielectric layer 292 is formed covering the second cap layer 282 and the transient TSV 280 and then dual damascene interconnection structures 290_1 and 290_2 are formed in the second inter-layer dielectric layer 292. The second inter-layer dielectric layer 292 may be a multi-layered structure comprising TEOS-based silicon dioxide, SiC, SiN, SiON, SiCN and low-k dielectric materials. The low-k dielectric materials may be selected from fluorine-doped silicon dioxide, carbon-doped silicon dioxide, porous silicon dioxide, porous carbon-doped silicon dioxide, spin-on organic polymeric dielectrics and spin-on silicone based polymeric dielectric. Dual damascene interconnection structure 290_1 consists of a conductive via 295_1 and a metal one (M1) layer 296_1 in one structure and in direct contact with the contact 270. Dual damascene interconnection structure 290_2 consists of a plurality of conductive vias 295_2 (4 are shown in FIG. 5A) and a metal one (M1) layer 296_2 in one structure and in direct contact with the transient TSV 280. The materials used for the dual damascene interconnection structures comprise a barrier/glue material and a low-resistivity filling material. The barrier/glue material may be selected from Ta, TaN, Ti, TiN, W, WN, Mo, Mn, Cu, and the barrier/glue material preferably is Ta/TaN or Ti/TiN/Ti. The low-resistivity filling material may be selected from W, Cu, Al, poly silicon and the low-resistivity filling material preferably is Cu. The dual damascene interconnection structures 290_1 and 290_2 may be formed by forming via and trench holes in the second inter-layer dielectric layer 292, forming the barrier/glue and low-resistivity filling materials on the substrate filling in the via and trench holes, then performing a chemical mechanical polishing process to remove excess materials and form a global flat surface.

In FIG. 5A, it is clearly to see the height D1 of the dual damascene interconnection structures 290_1 (distance from top surface of the contact 270 to top surface of the dual damascene interconnection structures 290_1) is larger than the height D2 of the dual damascene interconnection structures 290_2 (distance from top surface of the transient TSV 280 to top surface of the dual damascene interconnection structures 290_2) since the dual damascene interconnection structures 290_1 not only penetrates the second inter-layer dielectric layer 292 but also penetrates the second cap layer 282.

Please refer to FIGS. 1-4 and 5B, which are schematic cross-sectional views illustrating a method of manufacturing an integrated structure with TSV in accordance with second embodiment of the present invention. The processes, materials and structures for FIG. 1-4 are the same as the ones explained in previous paragraphs, their descriptions will be omitted to save repetition. In this embodiment, after forming the contact 270 and the second cap layer 282, buffer conductive structures 283 and 284 are formed on the high-k metal gate transistor 250 and the contact 270 respectively. The buffer conductive structures 283 and 284 may use the processes and materials for contact 270 or damascene interconnection structures 290, so their details may be omitted to save repetition. It is noted that the buffer conductive structures 283 and 284 may be formed after the transient TSV 280 is completed or they may be formed before the big trench 283 is formed. After forming the buffer conductive structures 283 and 284, follow the processes of FIG. 5A to form the second inter-layer dielectric layer 292 covering the second cap layer 282, the transient TSV 280 and the buffer conductive structures 283 and 284 and then form dual damascene interconnection structures 290′_1, 290′_2 and 290′_3 in the second inter-layer dielectric layer 292. Dual damascene interconnection structure 290′_1 consists of a conductive via 295′_1 and a metal one (M1) layer 296′_1 in one structure and in direct contact with the buffer conductive structure 284. Dual damascene interconnection structure 290′_2 consists of a plurality of conductive vias 295′_2 (4 are shown in FIG. 5B) and a metal one (M1) layer 296′_2 in one structure and in direct contact with the transient TSV 280. Dual damascene interconnection structure 290′ 3 consists of a conductive vias 295′_3 and a metal one (M1) layer 296′_3 in one structure and in direct contact with the buffer conductive structure 283.

In FIG. 5B, it is clearly to see the height d4 of the buffer conductive structure 283 (distance from top surface of the transistor 250 to top surface of the buffer conductive structure 283) is larger than the height d5 of the buffer conductive structure 284 (distance from top surface of the contact 270 to top surface of the buffer conductive structure 284) due to the thickness of the first cap layer 272. Furthermore, not like in the first embodiment shown in FIG. 5A, all the dual damascene interconnection structures 290′_1, 290′_2 and 290′_3 in this embodiment share the same height.

Please refer to FIGS. 1-4 and 6A, which are schematic cross-sectional views illustrating a method of manufacturing an integrated structure with TSV in accordance with third embodiment of the present invention. The processes, materials and structures for FIG. 1-4 are the same as the ones explained in previous paragraphs, their descriptions will be omitted to save repetition. In this embodiment, after completing the transient TSV 280, a third cap layer 281 is formed before forming the second inter-layer dielectric layer 292. The material used for the third cap layer is similar to the ones used for the first and second cap layer. After forming the third cap layer 281, follow the processes of FIG. 5A to form the second inter-layer dielectric layer 292 covering the third cap layer 281 and then form dual damascene interconnection structures 390_1 and 390_2 in the second inter-layer dielectric layer 292 and the third cap layer 281. Dual damascene interconnection structure 390_1 consists of a conductive via 395_1 and a metal one (M1) layer 396_1 in one structure and in direct contact with the contact 270. Dual damascene interconnection structure 390_2 consists of a plurality of conductive vias 395_2 (4 are shown in FIG. 6A) and a metal one (M1) layer 396_2 in one structure and in direct contact with the transient TSV 280.

In FIG. 6A, it is similar to FIG. 5A that the height D1′ of the dual damascene interconnection structures 390_1 (distance from top surface of the contact 270 to top surface of the dual damascene interconnection structures 390_1) is larger than the height D2′ of the dual damascene interconnection structures 390_2 (distance from top surface of the transient TSV 280 to top surface of the dual damascene interconnection structures 390_2) since the dual damascene interconnection structures 390_1 not only penetrates the second inter-layer dielectric layer 292 and the third cap layer but also penetrates the second cap layer 282.

Please refer to FIGS. 1-4, 6A and 6B, which are schematic cross-sectional views illustrating a method of manufacturing an integrated structure with TSV in accordance with fourth embodiment of the present invention. The processes, materials and structures for FIG. 1-4 are the same as the ones explained in previous paragraphs, their descriptions will be omitted to save repetition. In this embodiment, after forming the third cap layer 281, buffer conductive structures 283′ and 284′ are formed on the high-k metal gate transistor 250 and the contact 270 respectively. The buffer conductive structures 283′ and 284′ may use the processes and materials for contact 270 or damascene interconnection structures 290, so their details may be omitted to save repetition. After forming the buffer conductive structures 283′ and 284′, follow the processes of FIG. 5A to form the second inter-layer dielectric layer 292 covering the third cap layer 282 and the buffer conductive structures 283′ and 284′ and then form dual damascene interconnection structures 390′_1, 390′_2 and 390′_3 in the second inter-layer dielectric layer 292. Dual damascene interconnection structure 390′_1 consists of a conductive via 395′_1 and a metal one (M1) layer 396′_1 in one structure and in direct contact with the buffer conductive structure 284′. Dual damascene interconnection structure 390′_2 consists of a plurality of conductive vias 395′_2 (4 are shown in FIG. 6B) and a metal one (M1) layer 396′_2 in one structure and in direct contact with the transient TSV 280. Dual damascene interconnection structure 390′_3 consists of a conductive vias 395′_3 and a metal one (M1) layer 396′_3 in one structure and in direct contact with the buffer conductive structure 283′.

In FIG. 6B, it is quite different from the previous embodiments that the height D1″ of the dual damascene interconnection structures 390′_1 (distance from top surface of the contact 270 to top surface of the dual damascene interconnection structures 390′_1) is smaller than the height D2″ of the dual damascene interconnection structures 390′_2 (distance from top surface of the transient TSV 280 to top surface of the dual damascene interconnection structures 390′_2) due to the buffer conductive structures 283′ and 284′. Furthermore, the height d4′ of the buffer conductive structure 283′ (distance from top surface of the transistor 250 to top surface of the buffer conductive structure 283′) is larger than the height d5′ of the buffer conductive structure 284′ (distance from top surface of the contact 270 to top surface of the buffer conductive structure 284′) due to the thickness of the first cap layer 272.

Now refer to FIG. 7, which shows a schematic final result of the integrated structure with TSV in accordance with first embodiment (corresponding to FIG. 5A) of the present invention. After completing the integrated structure shown in FIG. 5A, form the higher level interconnection layer 1000. The higher level interconnection layer 1000 may comprise one or more inter-metal dielectric layers, one or more dual damascene interconnection structures, one or more passive devices such as MIM capacitors, inductors, resistors, one or more test structures, and one or more pads. After completing the higher level interconnection layer 1000, flip the substrate 100 and perform a grinding/polishing/thinning process on the backside of the substrate 100 in order to expose the conductive via 282 and to complete the TSV 300. Although FIG. 7 only shows the schematic final result of the first embodiment shown in FIG. 5A, other embodiments (that is FIG. 5B, 6A and 6B) can follow the same processes to fabricate the higher level interconnection layer 1000 and complete the TSV 300. The processes to fabricate the higher level interconnection layer 1000 and complete the TSV 300 would not change the geometric features described with respect to each embodiment.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An integrated structure, comprising:
a substrate with a first dielectric layer and a second dielectric cap layer disposed thereon in sequence;
a metal gate transistor with a high-k gate dielectric layer on the substrate, a gate electrode embedded within the first dielectric layer and a source/drain within the substrate;
a first metal contact, penetrating the first dielectric layer and being in direct contact with the source/drain; and
a through-silicon via penetrating the second dielectric cap layer, the first dielectric layer and the substrate.

2. The integrated structure of claim 1, wherein the top surface of the first metal contact is higher than the top surface of the metal electrode.

3. The integrated structure of claim 1, wherein the top surface of the through-silicon via is higher than the top surface of the first metal contact.

4. The integrated structure of claim 1, wherein the first dielectric layer comprises a first inter-layer dielectric layer and a first dielectric cap layer.

5. The integrated structure of claim 4, wherein the top surface of the first metal contact is coplanar with the first dielectric cap layer while the gate electrode coplanar with the first inter-layer dielectric layer.

6. The integrated structure of claim 1, wherein the top surface of the through-silicon via is coplanar with the second dielectric cap layer.

7. The integrated structure of claim 1, wherein the gate electrode comprises a U-shaped work function metal layer and a low-resistivity filling metal layer.

8. The integrated structure of claim 1, wherein the gate electrode comprises aluminum, the first metal contact comprises tungsten and the through-silicon via comprises copper.

9. The integrated structure of claim 1, further comprising a second dielectric layer disposed on the second dielectric cap layer covering the through-silicon via.

10. The integrated structure of claim 9, further comprising a first interconnect structure penetrating the second dielectric layer in connection to the through-silicon via and a second interconnect structure penetrating the second dielectric layer and the second dielectric cap layer in connection to the first metal contact.

11. The integrated structure of claim 10, wherein the second dielectric layer comprises a second inter-layer dielectric layer and a third dielectric cap layer.

12. The integrated structure of claim 1, further comprising a first buffer conductive structure disposed on the gate electrode and a second buffer conductive structure disposed on the first metal contact.

13. The integrated structure of claim 12, wherein the top surface of the first buffer conductive structure and the top surface of the second buffer conductive structure are coplanar with second dielectric cap layer.

14. The integrated structure of claim 13, further comprising a second dielectric layer disposed on the second dielectric cap layer covering the through-silicon via, the first buffer conductive structure and the second buffer conductive structure.

15. The integrated structure of claim 14, further comprising a first interconnect structure penetrating the second dielectric layer in connection to the through-silicon via, a second interconnect structure penetrating the second dielectric layer in connection to the first buffer conductive structure and a third interconnect structure penetrating the second dielectric layer in connection to the second buffer conductive structure.

16. The integrated structure of claim 1, further comprising a third dielectric cap layer covering the second dielectric cap layer and through-silicon via.

17. The integrated structure of claim 16, further comprising a first buffer conductive structure disposed on the gate electrode and a second buffer conductive structure disposed on the first metal contact.

18. The integrated structure of claim 17, wherein the bottom surface of the first buffer conductive structure is lower than the bottom surface of the second buffer conductive structure.

19. The integrated structure of claim 18, wherein the top surface of the first buffer conductive structure and the top surface of the second buffer conductive structure are coplanar with third dielectric cap layer.

20. The integrated structure of claim 19, further comprising a second inter-layer dielectric layer covering the third dielectric cap layer.
